(19) United States
(12) Patent Application Publication
(10) Pub. No.: US 2008/0054363 A1
(43) Pub. Date: Mar. 6, 2008

(54) DUAL GATE CMOS SEMICONDUCTOR DEVICE AND METHOD FOR MANUFACTURING THE SAME

(76) Inventor: Haeng-Leem Jeon, Seoul (KR)

Correspondence Address: SHERR & NOURSE, PLLC, 620 HERNDON PARKWAY, SUITE 200, HERNDON, VA, 20170, US

(21) Appl. No.: 11/844,635

(22) Filed: Aug. 24, 2007

(30) Foreign Application Priority Data
Aug. 31, 2006 (KR) 10-2006-0083833

(51) Int. Cl. H01L 21/8238; H01L 29/94

(52) U.S. Cl. 257/369; 438/199; 257/E29.345; 257/E21.632

(57) ABSTRACT

A dual gate Complementary Metal Oxide Semiconductor (CMOS) device includes a gate electrode of PMOS transistor implanted with germanium and indium ions and formed on a gate insulating film; a gate electrode of NMOS transistor not implanted with germanium and indium ions and formed on the gate insulating film; a source/drain region formed in a substrate exposed at both sides of the gate electrodes of the PMOS and NMOS transistors; and metal silicides formed on the source/drain region and the gate electrodes. A method for manufacturing a dual gate CMOS device, the method includes forming a gate insulating film; forming a polycrystalline silicon layer; forming an ion implantation mask; implanting germanium (Ge) and indium (In) ions into a PMOS transistor region of the substrate; and removing the ion implantation mask, patterning the polycrystalline silicon layer, and forming gate electrodes for PMOS and NMOS transistors.

The present application claims priority under 35 U.S.C. 119 and 35 U.S.C. 365 to Korean Patent Application No. 10-2006-0083833 (filed on Aug. 31, 2006), which is hereby incorporated by reference in its entirety.

### BACKGROUND

Aspects of semiconductor manufacturing technology have focused on increasing the integration of semiconductor devices (e.g., achieving smaller scale devices). As integration has increased, the ion implantation process plays an important role in achieving a low electric field in a channel/junction region because of a characteristic of the semiconductor device. In particular, the ion implantation process should allow application of high doses and still result in a shallow junction characteristic.

In some semiconductor manufacturing processes, ion implantation uses dopants such as boron (B), indium (In), and arsenic (As). In the case of boron (B) ion implantation, B or BF₂ are typically used. Specifically, boron (B) may be used as the dopant for a P⁺ polycrystalline region when forming a dual gate (a combination of an N⁺ polycrystalline gate of an NMOS transistor and a P⁺ polycrystalline gate of a PMOS transistor) applied to a low power and high speed semiconductor device among sub-100 nm-class high-integration semiconductor devices.

However, when such a dual gate is formed according to a method that includes boron ion implantation, there are a variety of drawbacks that occur. For example, one drawback is the occurrence of Poly Depletion Effect (PDE) due to insufficient activation of dopants. Another drawback that commonly occurs is that of infiltration of boron in which boron (B) passes through a gate insulating film and diffuses into a silicon substrate at the P⁺ polycrystalline gate.

There have been attempts to address these drawbacks, but such attempts have there own additional problems. One method uses a gate nitride oxide film while another method uses an epitaxial polycrystalline silicon-germanium (Poly Si—Ge) during the formation process.

In the attempted method that uses the polycrystalline silicon-germanium, a Fermi energy level can be positioned near a middle of a silicon band gap according to a germanium content. This achieves a symmetrical threshold voltage that allows an NMOS transistor and a PMOS transistor to operate in a surface channel form, thereby improving a gate characteristic.

In the attempted method that uses the gate nitride oxide film, the gate nitride oxide film is formed to increase a concentration of nitrogen within a gate insulating film, in an attempt to prevent infiltration of boron (B) into a silicon substrate that typically occurs as the gate insulating film gets smaller in thickness when trying to achieve high integration of a semiconductor device.

However, the method using the polycrystalline silicon-germanium has a drawback that an additional epitaxial process is required, thereby increasing the complexity of implementing such a method. The method using the gate nitride oxide film has a drawback that a concentration of nitrogen increases, thereby reducing a mobility of an NMOS transistor, thereby reducing its performance.

### SUMMARY

Embodiments described herein relate to a method for manufacturing a semiconductor device. Such a method includes implanting germanium (Ge) and indium (In) ions into a PMOS transistor on a polycrystalline silicon layer formed on a substrate while avoiding implanting the germanium (Ge) and indium (IN) ions into an NMOS transistor region on the polycrystalline silicon layer formed on the substratea; and forming gate electrodes for the PMOS and NMOS transistors.

Embodiments relate to a method for manufacturing a semiconductor device. In accordance with this method, a device may be made by forming an ion implantation mask covering an NMOS transistor region on a polycrystalline silicon layer formed on a substrate; then implanting germanium (Ge) and indium (In) ions into a PMOS transistor region of the substrate exposed by the ion implantation mask; and finally forming gate electrodes for the PMOS and NMOS transistors.

Embodiments relates to an apparatus that includes a) a gate electrode of PMOS transistor implanted with germanium and indium ions; b) a gate electrode of NMOS transistor free of implanted germanium and indium ions; and c) a source/drain region formed in a substrate exposed at both sides of the gate electrodes of the PMOS and NMOS transistors by implantation of impurity ions into respective NMOS and PMOS transistor regions.

### DRAWINGS

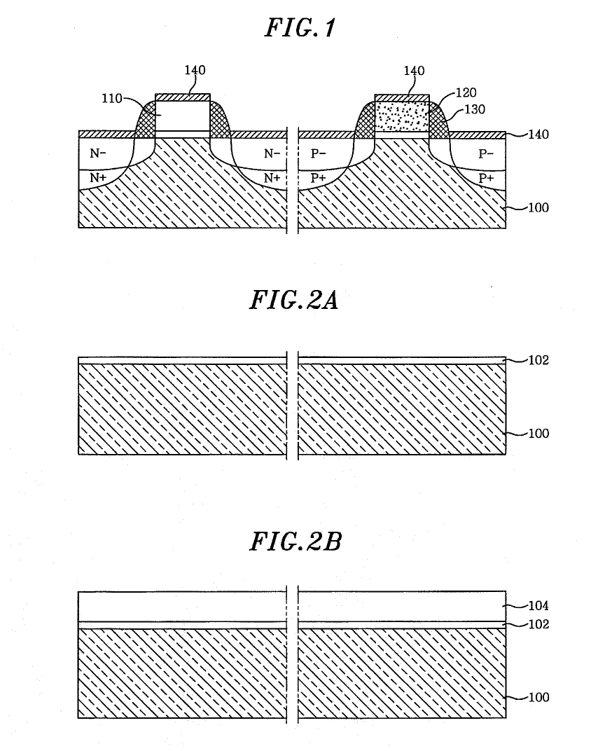

Example FIG. 1 illustrates a cross-sectional diagram of the architecture of a dual gate CMOS device, in accordance with embodiments.

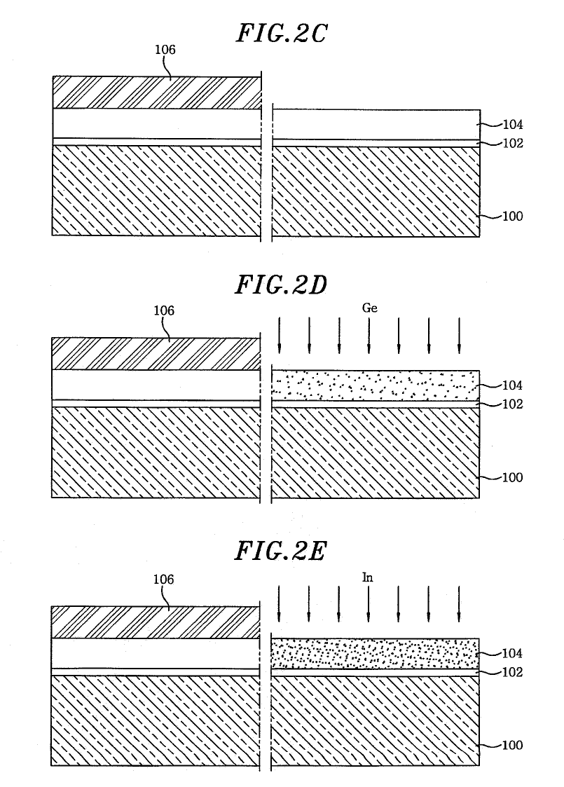

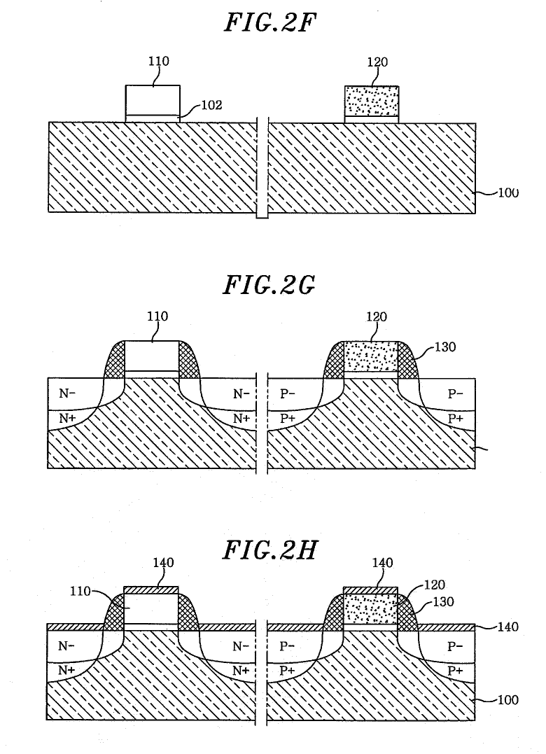

Example FIGS. 2A to 2H depict cross-sectional diagrams illustrating a method for manufacturing a dual gate CMOS device, according to embodiments.

### DESCRIPTION

As shown in example FIG. 1, a dual gate CMOS device includes a gate electrode 120 of a PMOS transistor implanted with germanium (Ge) and indium (In) ions and formed on a gate insulating film; a gate electrode 110 of an NMOS transistor not implanted with germanium (Ge) and indium (In) ions and formed on the gate insulating film; source/drain regions formed in a substrate exposed at both sides of the gate electrodes 110 and 120 of the NMOS and PMOS transistors by implantation of impurity ions into respective NMOS and PMOS transistor regions; and metal silicides 140 formed on the source/drain region and the gate electrodes 110 and 120 by laminating and annealing a metal layer on a whole surface of the substrate including the gate electrodes 110 and 120.

Spacers 130 can be formed at sidewalls of the gate electrodes 110 and 120 of the NMOS and PMOS transistors. The source/drain region can be formed to have a Lightly Doped Drain (LDD) structure.

A method for manufacturing the above-constructed dual gate CMOS device is described with reference to example FIGS. 2A to 2H. Example FIGS. 2A to 2H depict cross-sectional diagrams illustrating a method for manufacturing a dual gate CMOS device according to embodiments.

Referring to example FIG. 2A, a gate insulating film 102 is formed on a semiconductor substrate 100. In general, before the forming of the gate insulating film 102, a well region is typically formed by impurity doping in the semiconductor substrate 100 and device isolation is implemented using various techniques such as, for example, a Shallow Trench Isolation (STI) process. The gate insulating film 102 has a thickness of between approximately 40 Å to approximately 70 Å. The gate insulating film 102 can be formed differently in an NMOS transistor region and a PMOS transistor region. In a recent dual gate CMOS device, there are many cases in which a gate insulating film 102 of a PMOS transistor is formed to have a thickness of between approximately 20 Å to approximately 40 Å in order to increase both performance and integration of the device. The gate insulating film 102 can, for example, be a silicon oxide film formed by oxidizing a semiconductor substrate at high temperature in oxygen atmosphere.

Referring to example FIG. 2B, a polycrystalline silicon layer 104 is formed to have a predetermined thickness on the semiconductor substrate 100 including the gate insulating film 102. In general, the polycrystalline silicon layer 104 is formed using a CVD method with a process chamber having an atmospheric pressure of several Torr or a room pressure and a source gas such as silane gas (SiH₄) flowing. However, other methods of forming the polycrystalline silicon layer 104 are contemplated as well without departing from the scope of the present invention.

Referring to example FIG. 2C, a photoresist is coated on the polycrystalline silicon layer 104. After that, a photoresist pattern 106, which is a well mask for exposing only the PMOS transistor region, is formed by exposure and development.

Referring to example FIG. 2D, germanium (Ge) ions are implanted into the polycrystalline silicon layer 104 of the PMOS transistor region with an ion implantation mask as the photoresist pattern 106. At this time, an amount of dose for ion implantation into the polycrystalline silicon layer 104 of the PMOS transistor region is similar with an amount of dose for ion implantation into a source/drain region or is equal to approximately 1E15 ions/cm² that is a little higher than the amount of dose for ion implantation into the source/drain region.

The above implantation of germanium ions causes the polycrystalline silicon layer 104 of the PMOS transistor region to be in an amorphous state, thereby preventing diffusion of boron (B) impurities to the gate electrode of the PMOS transistor region. The boron (B) impurities are doped into the PMOS transistor region in the future.

As shown in FIG. 2E, the polycrystalline silicon layer 104 of the PMOS transistor region is implanted with indium (In) ions with the same photoresist pattern 106 as an ion implantation mask. At this time, the amount of dose for ion implantation into the polycrystalline silicon layer 104 of the PMOS transistor region is equal to approximately 2.0E13 ions/cm². Furthermore, the energy for indium ion implantation is lower than energy for germanium ion implantation.

As such, indium can be implanted into the polycrystalline silicon layer 104 of the PMOS transistor region. The result is that there is a reduction in the concentration of boron (B) impurities that are doped into the gate electrode of the PMOS transistor region in the future.

An amount of dose for ion implantation and energy for ion implantation in the germanium (Ge) and indium (In) ion implantation processes in accordance with the principles of embodiments herein have a relationship with a redistribution of a concentration of germanium (Ge) to some extent. One of ordinary skill will readily recognize that optimal condition for ion implantation can be obtained by considering empirical related factors or through routine experiments.

Referring to example FIG. 2F, the photoresist pattern 106 is removed in a rinse process. After that, the polycrystalline silicon layer 104 and the gate insulating film 102 are patterned to form the gate electrodes 110 and 120 of the NMOS transistor and the PMOS transistor. The patterning of the polycrystalline silicon layer 104 is typically performed by forming a photoresist pattern for a gate electrode by coating, exposure, and development of a general photoresist and patterning the polycrystalline silicon layer 104 with the formed photoresist pattern as an etching mask. In the patterning process, the polycrystalline silicon layer 104 can be also annealed to cure a damage caused by etching at sidewalls.

After gate patterning, impurity doping may be performed to form the source/drain region. The impurity doping may be performed, for example, by ion implantation. In the ion implantation, the high-concentration ion implantation usually occurs separate from the low-concentration ion implantation. For example, the low-concentration ion implantation may first be performed for LDD formation for each of NMOS transistor region and the PMOS transistor region. Therefore, while the low-concentration ion implantation into the NMOS transistor region is being performed, the PMOS transistor region is usually protected using an ion implantation mask, and vice versa.

Referring to example FIG. 2G, low-concentration ion implantation (N⁻, P⁻) into each of the transistor regions is implemented. After that, an insulating film is conformally laminated throughout a whole surface of the resultant. After that, an anisotropic blanket etching process is performed. Accordingly, gate spacers 130 are formed at sidewalls of the gate electrodes 110 and 120. The spacers 130 are generally comprised of a silicon nitride film or a silicon oxide film. After the spacers 130 are formed, high-concentration ion implantation (N⁺, P⁺) for each of the NMOS and PMOS transistor regions may be performed.

For example, boron (B) ions may be implanted into the PMOS transistor region for the gate electrode 120 and the source/drain region. At the time of boron ion implantation, boron (B) impurities are prevented from diffusing to the gate electrode 120 of the PMOS transistor region because germanium (Ge) ions have been doped into the gate electrode 120 of the PMOS transistor region. In addition, though boron (B) impurities are doped into the gate electrode 120, the concentration thereof is significantly lowered, because indium (In) ions have been doped into the gate electrode 120.

After that, an annealing process is implemented to diffuse and activate implanted ions and compensate for a damage of the source/drain region caused by ion implantation. In the annealing process, the diffusion of boron (B) into the semiconductor substrate 100 is prevented because the concentration of boron (B) impurities within the gate electrode 120 has been reduced due to presence indium (In) ions.

For the NMOS transistor region, typically Arsenic (As) ions are implanted into the gate electrode 110 and the source/drain region.

Referring to example FIG. 2H, titanium or cobalt metal is deposited by Physical Vapor Deposition (PVD) to have a thickness of approximately 100 Å to approximately 300 Å over the semiconductor substrate 100 and is annealed. The deposited titanium or cobalt metal may then be etched. Thus, the titanium or cobalt is all removed from a portion excepting upper parts of the gate electrodes 110 and 120 and an exposed substrate on which silicides are formed through the annealing. Thus, metal silicides 140 are formed on the source/drain region and the upper parts of the gate electrodes 110 and 120.

As described above in the above embodiments, only a polycrystalline silicon layer of a PMOS transistor region is doped with germanium and indium using a well mask. Thus, a reduction of performance of a gate electrode of an NMOS transistor region can be suppressed. In addition, infiltration of impurities into a substrate can be prevented when impurity ions are implanted into the PMOS transistor region. And, a concentration of impurities implanted into a gate electrode can be reduced in impurity ion implantation, thereby stopping infiltration of impurities into the gate electrode and preventing a reduction of performance of a PMOS device.

Also, embodiments can prevent infiltration of impurity ions into a substrate occurring because a depletion of polycrystalline silicon, that is, infiltration that tends to occur when the thickness of the polycrystalline silicon is reduced to achieve higher integration. Thus, a reduction of performance of a device is prevented.

Although embodiments are described herein, it will be understood by those skilled in the art that various changes and modifications may be made without departing from the spirit and scope of the present disclosure as defined in the following claims.

What is claimed is:

1. An apparatus comprising:
a gate electrode of a PMOS transistor implanted with germanium and indium ions;
a gate electrode of an NMOS transistor free of implanted germanium and indium ions and
a source/drain region formed in a substrate exposed at both sides of the gate electrodes of the PMOS and NMOS transistors by implantation of impurity ions into respective NMOS and PMOS transistor regions.

2. The apparatus of claim 1, wherein the source/drain region has a Lightly Doped Drain (LDD) structure.

3. The apparatus of claim 1, wherein the impurity ions implanted into the PMOS transistor region comprise boron (B) ions.

4. The apparatus of claim 1, further comprising:
metal silicides formed on the source/drain region and each gate electrode.

5. The apparatus of claim 1, wherein the metal silicides are formed by laminating and annealing a metal layer on a whole surface of the substrate comprising the gate electrodes.

6. The apparatus of claim 1, wherein each of the gate electrodes is formed on a gate insulating film.

7. A method comprising:
forming an ion implantation mask covering an NMOS transistor region on a polycrystalline silicon layer formed on a substrate;
implanting germanium (Ge) and indium (In) ions into a PMOS transistor region of the substrate exposed by the ion implantation mask; and
forming gate electrodes for the PMOS and NMOS transistors.

8. The method of claim 7, further comprising:
removing the ion implantation mask and patterning the polycrystalline silicon layer.

9. The method of claim 7, further comprising:
forming a source/drain region in each of the NMOS transistor region and the PMOS transistor region.

10. The method of claim 9, wherein forming a source/drain region further comprises:
performing an ion implantation process.

11. The method of claim 9, wherein the source/drain region is formed to have a Lightly Doped Drain (LDD) structure.

12. The method of claim 10, wherein impurity ions implanted into the PMOS transistor region are boron (B) ions.

13. The method of claim 7, wherein the germanium ions are implanted with an amount of dose of approximately 1.0E15 ions/cm².

14. The method of claim 7, wherein the indium ions are implanted with an amount of dose of approximately 2.0E13 ions/cm².

15. A method comprising:
implanting germanium (Ge) and indium (In) ions into a PMOS transistor on a polycrystalline silicon layer formed on a substrate while avoiding implanting the germanium (Ge) and indium (IN) ions into an NMOS transistor region on the polycrystalline silicon layer formed on the substrate; and
forming gate electrodes for the PMOS and NMOS transistors.

16. The method of claim 15, further comprising:
forming a source/drain region in each of the NMOS transistor region and the PMOS transistor region.

17. The method of claim 16, wherein forming a source/drain region further comprises:
performing an ion implantation process.

18. The method of claim 16 wherein the source/drain region is formed to have a Lightly Doped Drain (LDD) structure.

19. The method of claim 17, wherein impurity ions implanted into the PMOS transistor region are boron (B) ions.

20. The method of claim 15, further comprising:
forming an ion implantation mask covering the NMOS transistor region on the polycrystalline silicon layer formed on the substrate;
